(19) United States
(12) Patent Application Publication
(10) Pub. No.: US 2013/0285202 A1
(43) Pub. Date: Oct. 31, 2013

(54) SEMICONDUCTOR DEVICE

(71) Applicant: ELPIDA MEMORY, INC., Tokyo (JP)

(72) Inventors: Kenichi KOYANAGI, Tokyo (JP); Takashi ARAO, Tokyo (JP); Naonori FUJIWARA, Tokyo (JP); Tomohiro UNO, Tokyo (JP)

(73) Assignee: ELPIDA MEMORY, INC., Tokyo (JP)

(21) Appl. No.: 13/794,854

(22) Filed: Mar. 12, 2013

(30) Foreign Application Priority Data
Apr. 27, 2012 (JP) 2012-103202

(51) Int. Cl. H01L 49/02

(52) U.S. Cl. CPC H01L 28/60
USPC 257/532

(57) ABSTRACT

To provide a semiconductor device including a capacitor which includes a cylindrical or columnar lower electrode, a support film in contact with the upper portion of the lower electrode for supporting the lower electrode, a dielectric film covering the lower electrode and the support film, and an upper electrode facing the lower electrode with the dielectric film interposed therebetween, wherein the dielectric film has a first thickness on the upper surface of the support film and a second thickness thinner than the first thickness on the side surface of the lower electrode, and thereby the mechanical strength of the support film is increased.

### BACKGROUND OF THE INVENTION

1. Field of the Invention

The present invention relates to a semiconductor device, and more particularly relates to a semiconductor device including a 3-dimentional capacitor supported by a support film.

2. Description of the Related Art

With progress of miniaturization of semiconductor devices, a memory cell including in a DRAM (Dynamic Random Access Memory) has also been reduced in area. In order to secure sufficient electrostatic capacitance in a capacitor configuring the memory cell, the capacitor is generally formed in a three-dimensional shape. Specifically, the surface area of the capacitor can be increased in such a manner that a lower electrode of the capacitor is formed into a 3-dimentional shape such as a cylindrical and pillar shapes, and that the side wall of the lower electrode is used for a capacitive portion.

Conventionally, the lower electrode of the capacitor, which has a large aspect ratio, is formed in such a manner that, after a lower electrode material is formed on the inner surface of a deep hole formed in a sacrificial insulating film (mainly a silicon oxide film), the thick sacrificial insulating film remaining outside the lower electrode material is removed. With the reduction in the area of the memory cell, the bottom area of the lower electrode is also reduced. Therefore, in the manufacturing process of removing the sacrificial insulating film to expose the side surface of the lower electrode, few lower electrodes may collapse and be short-circuited with the adjacent lower electrode, and such a phenomenon (collapse) is more likely to occur. In order to prevent the collapse of the lower electrode, there has been proposed a technique in which a support body serving as a support is arranged between the lower electrodes. For example, JP2010-262989A discloses that, in a capacitor having a lower electrode formed in a crown-shaped cylinder, a support body (support film) is used for preventing the collapse of the cylinder. The support film connects the upper portions of the cylinders together to prevent the collapse of the cylinders. The sacrificial insulating film is etched by hydrofluoric acid (HF), and hence the support film is formed of silicon nitride having high resistance to HF.

FIG. 1 is a schematic top view of the memory cell region. Further, FIG. 2 is a schematic sectional view taken along the line A-A′ in FIG. 1. A titanium nitride film, which is lower electrode 103, is formed in a crown shape on substrate 101, and support film 102 formed of a silicon nitride film is formed so as to support the upper portion of lower electrode 103. To this structure, a dielectric film will be formed on the surfaces of lower electrode 103 and support film 102. Further, a titanium nitride film serving as an upper electrode, and a polysilicon film used for filling gaps will be formed on the dielectric film to complete a DRAM capacitor.

When, after the formation of the dielectric film and the upper electrode, the substrate was seen from the above, it was found that cracks 104 were caused in support film 102, as shown in FIG. 1. It is considered that cracks 104 were caused by the stresses of the dielectric film, the upper electrode film, and the polysilicon film.

In order to prevent the cracks from being caused, a measure of increasing the plan-view area of support film 102 is considered. However, in order to form the dielectric film and the upper electrode, it is preferred to increase the area of the opening portion formed in the support film, that is, to reduce the area of the support film. When the area of the opening portion is reduced, raw material gases for forming the films of the dielectric film and the upper electrode do not sufficiently reach the lower portion of the lower electrode, so as to cause, in the film formation, a defect that these films are not formed at the lower portion of the lower electrode.

Further, it is conceivable, as a measure, to form thickly the support film from the beginning. However, in the case where the support film is formed thickly, such a thick film causes a problem that, when a hole used as a mold for forming the lower electrode is processed, the shape of the hole is deteriorated in the dry etching processing. Further, the productivity is lowered due to increase of time required for the formation of the support film and the dry etching processing. In addition, even in the case where the support film is formed thickly, the amount of the sacrificial insulating film, which is etched after formation of the lower electrode film, is increased as the aspect ratio of the lower electrode increases. Thereby, even the silicon nitride film used as the support film is etched to be thin, which results in a problem that the mechanical strength of the support film is reduced.

### SUMMARY OF THE INVENTION

With an embodiment according to the present invention, there is provided a semiconductor device including a capacitor which includes

a cylindrical or columnar lower electrode,

a support film in contact with the upper portion of the lower electrode,

a dielectric film covering the lower electrode and the support film, and

an upper electrode facing the lower electrode with the dielectric film interposed therebetween,

wherein a first thickness of the dielectric film on the upper surface of the support film is larger than a second thickness of the dielectric film on the side surface of the lower electrode at a position lower than the position at which the dielectric film is in contact with the support film.

With another embodiment according to the present invention, there is provided a semiconductor device including:

a first conductor film perpendicularly standing on a substrate;

a support film in contact with the upper portion of the first conductive film; and

a dielectric film covering the first conductor film and the support film,

wherein the dielectric film has a first thickness on the upper surface of the support film and a second thickness thinner than the first thickness on the side surface of the first conductor film at a position lower than the position at which the first conductor film is in contact with the support film.

Since a dielectric film makes being thicker on the support film than that on the side surface of a lower electrode, the mechanical strength of the support film can be improved.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a schematic top view for explaining a problem of the related art;

FIG. 2 is a schematic sectional view for explaining the problem of the related art;

FIG. 3 is a schematic top view of a semiconductor device according to an exemplary embodiment;

FIG. 4 is a schematic sectional view of a semiconductor device according to an exemplary embodiment;

FIG. 5 is an enlarged view of portion P1 shown in FIG. 4;

FIG. 6 to FIG. 10 are process sectional views for explaining a semiconductor device manufacturing method as an exemplary embodiment;

FIG. 11 is a schematic sectional view of a semiconductor device according to another exemplary embodiment.

FIG. 12 is a flow chart for explaining a dielectric film forming process in an example;

FIG. 13 is a graph showing a relationship between the film formation temperature and the film thickness of the dielectric film formed in the dielectric film forming process as the example;

FIG. 14 is a graph showing a change in the number of crack occurrences with respect to the ratio of first thickness (dA) of the dielectric film to second thickness (dB) of the dielectric film in the example.

FIG. 15 is a flow chart for explaining a dielectric film forming process in another example; and

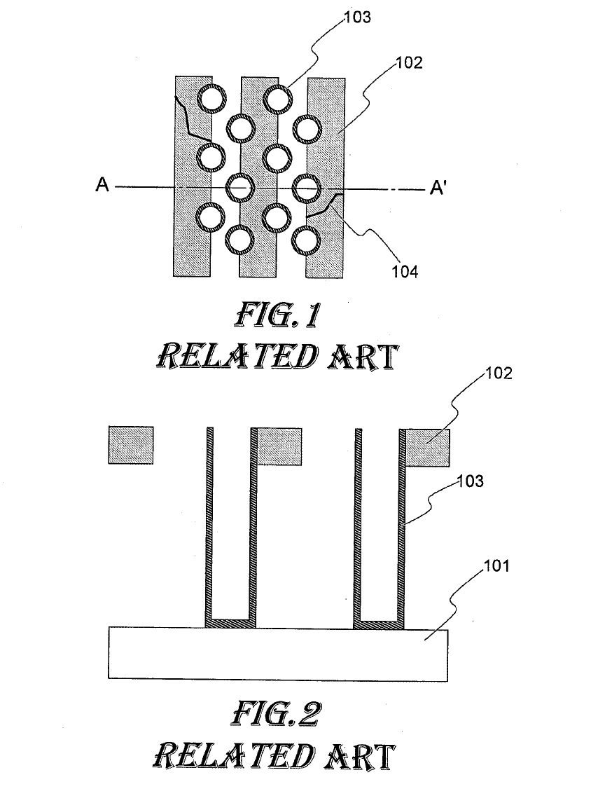

### DETAILED DESCRIPTION OF THE PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purpose.

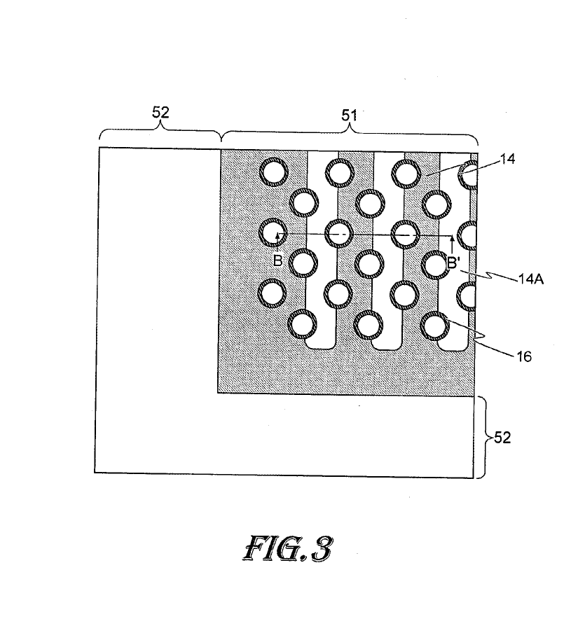

FIG. 3 is a schematic top view of a semiconductor device according to an exemplary embodiment. In this exemplary embodiment, a DRAM including memory cell region 51 and peripheral circuit region 52 will be described as the semiconductor device, the present invention is not limited to a DRAM. FIG. 3 only shows a relationship between support film 14 and lower electrode 16 and the position of memory cell region 51 and peripheral circuit region 52, other configurations are omitted. As shown in FIG. 3, support film 14 is provided within memory cell region 51 that is surrounded by peripheral circuit region 52. In support film 14, openings 14A are formed at predetermined intervals.

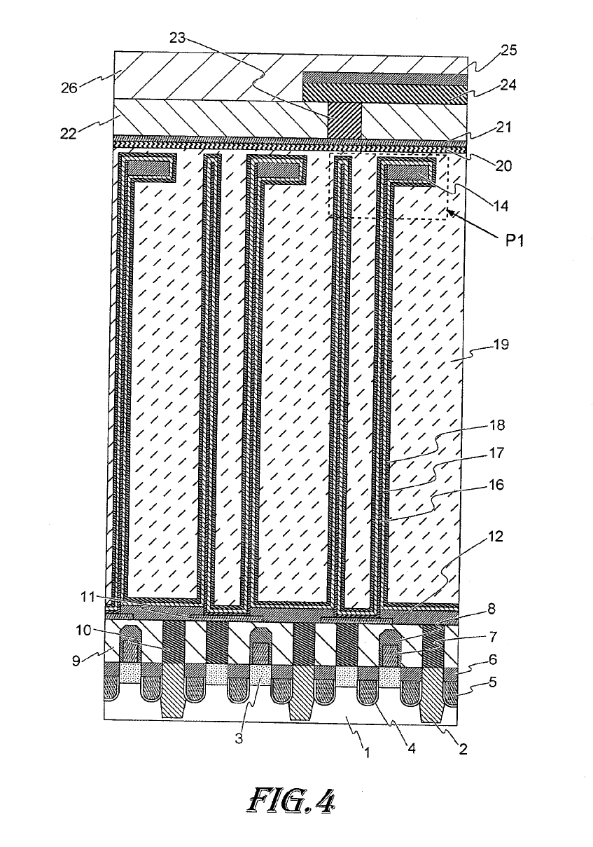

FIG. 4 is a schematic sectional view of a semiconductor device according to an exemplary embodiment and is corresponding to a view taken along line B-B′ in FIG. 3. FIG. 5 is an enlarged view of portion P1 shown in FIG. 4.

In an active region of semiconductor substrate 1, defined by element isolation region 2, impurity diffusion layer 3 is formed, and buried gate electrode 5 is formed in semiconductor substrate 1 via gate insulating film 4. Cap layer 6 is formed on buried gate electrode 5. Bit line 7 is connected to impurity diffusion layer 3 shared by two transistors adjacent to each other, and bit-covering film 8 is formed to cover bit line 7. Further, impurity diffusion layer 3, which is not shared by the two transistors adjacent to each other, is connected to capacitor contact pad 11 via capacitor contact plug 10. Lower electrode 16 of a capacitor is formed on capacitor contact pad 11, and the bottom portion of lower electrode 16 is held by stopper film 12 formed to cover capacitor contact pad 11. On the other hand, the upper portion of lower electrode 16 is held by support film 14.

On the surfaces of lower electrode 16 and support film 14, dielectric film 17 is formed followed by an upper electrode including, for example, second conductor film 18, filling film 19 to fill gaps under support film 14, adhesive film 20 and plate electrode 21. Second conductor film 18 is preferably made of the same material of lower electrode 16. Filling film 19 is preferably made of impurity-doped silicon-germanium (SiGe). Plate electrode 21 made of a metal material is formed on filling film 19 via adhesive film 20 made of impurity-doped silicon. Interlayer insulating films 22 and 26 are stacked on plate electrode 21, and contact plug 23, which connects plate electrode 21 to upper wiring 24, is formed in interlayer insulating film 22.

As shown in FIG. 5, a feature of the present invention is that first thickness dA of dielectric film 17 on the upper surface of support film 14 is larger than second thickness dB of dielectric film 17 on the side surface of lower electrode 16. That is, in the present invention, support film 14 whose thickness is reduced is restored by dielectric film 17 that is formed subsequently to support film 14. Usually, dielectric film 17 is formed by an ALD method that is excellent in coverage performance, but in the present invention, a process based on a CVD condition is inserted into the film forming sequence executed by the process of the ALD method. The CVD condition has a feature that the coverage performance of the dielectric film is deteriorated and thereby the dielectric film is formed so that the thickness of the dielectric film is increased from the lower portion to the upper portion of the dielectric film. By making use of this feature, the thickness of dielectric film 17 can be made larger on the upper portion of the lower electrode, especially on the upper surface of support film 14, than that on the other portion of the lower electrode, and thereby a mechanical strength of support film 14 is improved. In particular, the present invention is effective in the case where the thickness of support film 14 is 60 nm or less, particularly 50 nm or less, and more particularly 40 nm or less. Usually, first thickness dA is a maximum thickness of dielectric film 17 if support film 14 is in contact with the upper side edge of lower electrode 16. In that case, the top surface of lower electrode 16 is in a position equal to or lower than the upper surface of support film 14. Of course, the upper surface of the lower electrode can protrude from the upper surface of the support film. However, because the protruded part of the lower electrode becomes large, a portion used as capacity is reduced, it is not preferable to excessively protrude.

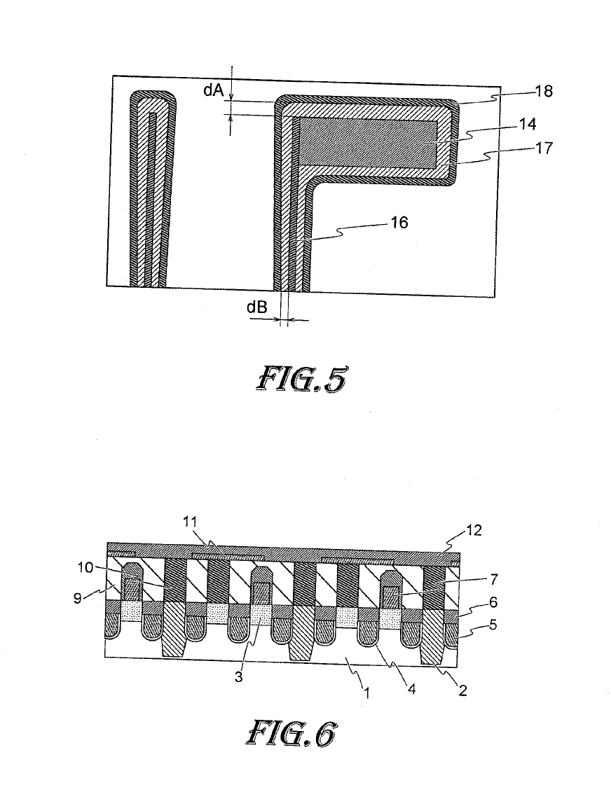

Next, the manufacturing process of the semiconductor device according to the present invention will be described with reference to FIG. 6 to FIG. 10.

First, as shown in FIG. 6, element isolation trenches (trenches) are formed by using a photolithography technique and a dry etching technique. Next, a silicon nitride film (SiN) or a silicon oxide film (SiO₂) is filled in the element isolation trenches by a CVD (Chemical Vapor Deposition) method, so that element isolation regions 2 are formed. Next, gate trenches are formed on semiconductor substrate 1. In each of the gate trenches, gate insulating film 4 and tungsten (W) are formed respectively by a thermal oxidation method and a sputtering method, and then cap layer 6 made of a silicon nitride film (SiN) is filled. Thereby, a buried word line (the plan view of which is not shown) of a metal structure including tungsten is formed. Next, by using a photolithography technique and an ion implantation method, impurity diffusion layer 3 is formed in the portions of semiconductor substrate 1, which are not covered by the word line. By the above processing, buried MOS transistors, each of which is constituted of gate insulating film 4, the buried word line serving as gate electrode 5 and impurity diffusion layers 3 serving as the source/drain, are formed. Next, bit line 7 including tungsten is formed in such a manner that a tungsten film and a silicon nitride film are stacked by a CVD method and then the tungsten film is patterned by a photolithography technique and a dry etching technique using the silicon nitride film as a hard mask. Next, a sidewall insulating film covering the side surfaces of bit line 7 is formed in such a manner that a silicon nitride film is formed by a CVD method so as to cover bit line 7 and is then etched back. In figures, the silicon nitride films of the hard mask and the sidewall are called as bit-covering film 8. Next, interlayer insulating film 9, which is a silicon oxide film, is formed by a CVD method so as to cover bit lines 7, and then the surface of interlayer insulating film 9 is flattened by a CMP (Chemical Mechanical Polishing) method. Next, a contact hole exposing impurity diffusion layer 3 is formed in interlayer insulating film 9, and then the capacitor contact plug is formed in the contact hole. Then, capacitor contact pad 11, which is connected to capacitor contact plug 10, is formed in such a manner that a tungsten film is formed on interlayer insulating film 9 by a CVD method and is then patterned by a photolithography technique and a dry etching technique. Next, a silicon nitride film is formed by a CVD method so as to cover capacitor contact pad 11, and thereby stopper film 12 is formed.

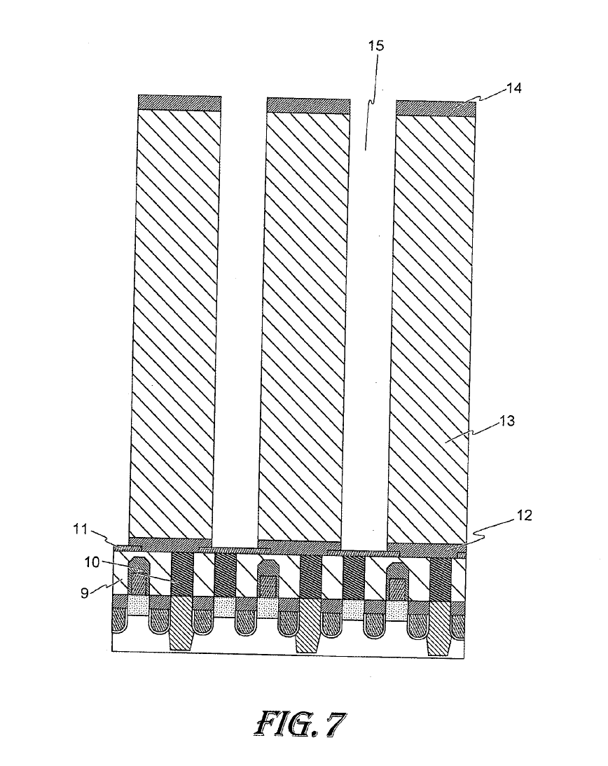

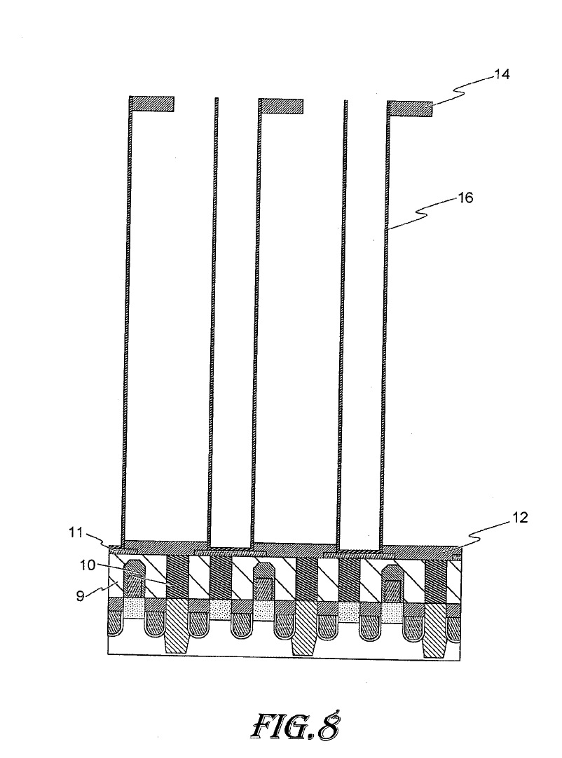

Next, as shown in FIG. 7, sacrificial insulating film 13 that is a silicon oxide film, and support film 14 that is a silicon nitride film are formed on stopper film 12 by a CVD method. Next, cylinder holes 15, each of which penetrates support film 14, sacrificial insulating film 13 and stopper film 12, are formed by a photolithography technique and a dry etching technique. Thereby, the upper surface of capacitor contact pad 11 is exposed on the bottom of cylinder hole 15.

Next, a first conductor film that is a titanium nitride (TiN) film serving as a lower electrode is formed by an SFD (Sequential Flow Deposition) method so as to cover the inner surface of cylinder hole 15. At this time, the film thickness of the first conductor film is set to be less than a half of the inner diameter of cylinder hole 15, and hence cylinder hole 15 is left without being completely filled by the first conductor film. Next, a cover film (not shown), which is a silicon oxide film, is formed by a CVD method so as to fill cylinder hole 15.

Next, as shown in FIG. 8, support film 14 in peripheral circuit region 52 is removed by using a photolithography technique and a dry etching technique, and thereby the upper surface of sacrificial insulating film 13 in peripheral circuit region 52 is exposed. At this time, the film thickness of photoresist is adjusted so that the cover film and the first conductor film on support film 14 in memory cell region 51 are concurrently removed with completion of removal of support film 14 in peripheral circuit region 52. As a result, lower electrode 16 is also formed at the same time with completion of removal of support film 14. In memory cell region 51, openings 14A are formed in support film 14 as shown in FIG. 3. Next, sacrificial insulating film 13, which is a silicon oxide film, and the cover film filling the cylinder hole are completely removed by a wet etching technique using hydrofluoric acid (HF). At this time, interlayer insulating film 9 covered by stopper film 12, lower electrode 16, and support film 14 are left without being removed. This is because the silicon nitride film constituting stopper film 12 and support film 14, and titanium nitride constituting lower electrode 16 are not removed by the hydrofluoric acid. Lower electrodes 16 adjacent to each other are connected to each other by remaining support film 14 and hence are held upright side by side without collapsing. The inner surface and the outer side surface of lower electrode 16 are exposed by removing sacrificial insulating film 13.

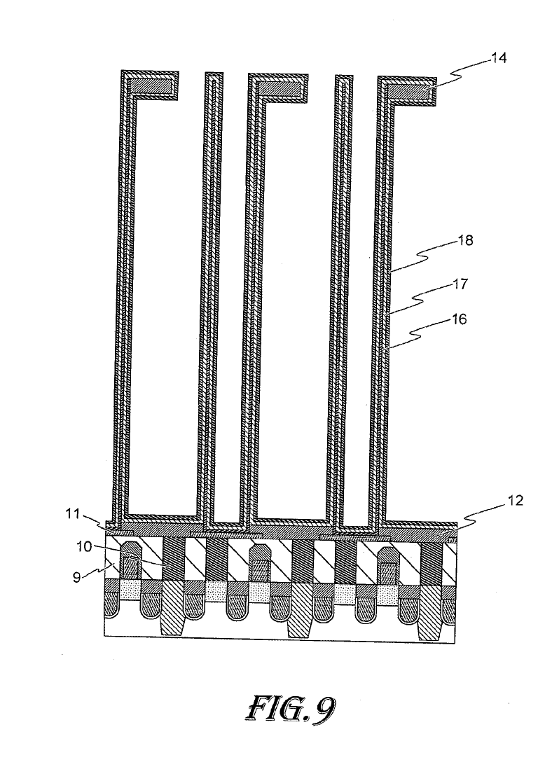

Next, as shown in FIG. 9, dielectric film 17, which is a thin film formed by alternately laminating aluminum oxide (Al₂O₃) and zirconium oxide (ZrO₂), is formed by an ALD (Atomic Layer Deposition) method so as to cover the surface of lower electrode 16. At this time, by the film forming process according to the present invention, a CVD condition is added to the ALD process so that first thickness dA of dielectric film 17 on the upper surface of support film 14 becomes larger than second thickness dB of dielectric film 17 formed on the side surface of lower electrode 16 and located at a position lower than the position at which dielectric film 17 is in contact with support film 14. Note that the film forming conditions of the dielectric film will be described in Examples described below.

Next, second conductor film 18, which is a titanium nitride film, is formed by an SFD method so as to cover the surface of dielectric film 17. At this time, as shown in FIG. 5, dielectric film 17 and second conductor film 18 uniformly cover the side surface portion of lower electrode 16. Further, the surfaces of support film 14 and stopper film 12 are also covered by dielectric film 17 and second conductor film 18. The SFD method is a method that can efficiently form a highly precise thin film by supplying a combination of two or more kinds of process gases for each film forming process. When the first conductor film of lower electrode 16 and second conductor film 18 are formed by the SFD method, the titanium nitride film is formed by alternately repeating a process of simultaneously flowing titanium tetrachloride (TiCl₄) and ammonia (NH₃) used as process gases, and a process of flowing only ammonia.

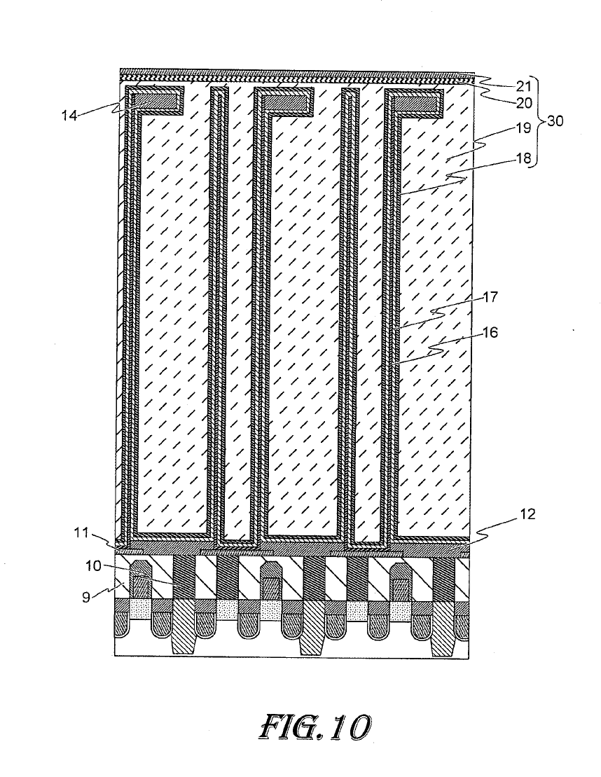

Next, as shown in FIG. 10, filling film 19, which is a boron (B) doped silicon germanium (SiGe) film, is formed on second conductor film 18 by an LPCVD (low pressure CVD) method. Next, adhesive film 20, which is a boron (B) doped polysilicon (Si) film, is formed on filling film 19 by an LPCVD method. After formation of filling film 19, a low resistance tungsten (W) film may be formed in the whole memory cell region, but there is a problem that the tungsten film is separated when the tungsten film is formed directly on the boron doped SiGe film. In the exemplary embodiment, a boron doped polysilicon film is formed as an adhesive film in order to avoid the film separation problem. It is preferred that the boron doped polysilicon film is formed by using a known thin film forming apparatus continuously subsequently to the formation of the boron doped SiGe film. At this time, the process conditions are set such that monosilane (SiH₄) and boron trichloride (BCl₃) are used as raw material gases, such that the flow rates of the gases are respectively set to 787 sccm (SiH₄) and 3.15 sccm (BCl₃), and such that the heating temperature and the pressure are respectively set to 450° C. and 40 Pa. Note that the monosilane (SiH₄) and the boron trichloride (BCl₃) are introduced from same gas inlet. Next, plate electrode 21, which is a tungsten film, is formed by a sputtering method so as to cover the surface of adhesive film 20. Next, unnecessary films in the peripheral circuit region are removed by using a photolithography technique and a dry etching technique. Here, the unnecessary films are plate electrode 21, adhesive film 20, filling film 19, and second conductor film 18. When these unnecessary films are removed, the surface of dielectric film 17 formed on stopper film 12 in the peripheral circuit region, and the side surface of filling film 19 in the memory cell region are exposed. In this dry etching process, it is preferred to choose the etching gas properly in correspondence with each of the unnecessary films described above. Further, dielectric film 17 that is exposed is removed by dry etching. At this time, it is more preferred that, in order to enable the completion timing of the etching process to be easily determined, a process condition is selected to have a high etch selectivity between dielectric film 17 and stopper film 12.

When adhesive film 20 made of boron doped Si is formed at 450° C. as described above, adhesive film 20 is usually formed in an amorphous state (for example, when being formed on a silicon oxide film) and has no conductive property. However, as in the exemplary embodiment, when adhesive film 20 is formed on the boron doped SiGe film which is already formed in a polycrystalline state, epitaxial growth is performed by using the boron doped SiGe film itself as a seed crystal, so that the boron doped Si film is also formed in the polycrystalline state. Thereby, the boron doped Si film is also formed into a film having conductive property in the film forming stage.

The boron doped Si film is inferior in the step coverage to the boron doped SiGe film, and cannot completely fill the spaces left around the capacitor. Therefore, the boron doped Si film cannot be used in place of the boron doped SiGe film. As the state before formation of the boron doped Si film, it is preferred that, at the completion of formation of filling film 19, the upper surface of filling film 19 formed above the upper surface of capacitor is formed in a flat state. When the upper surface of filling film 19 is formed in a flat state, the poor step coverage of the boron doped Si film does not cause any problem. In the present invention, second conductor film 18, filling film 19, adhesive film 20 and plate electrode 21 constitute upper electrode 30 of the capacitor.

Finally, second interlayer insulating film 22, which is a silicon oxide film, is formed by a CVD method so as to cover the upper electrode of the capacitor in the memory cell region. Next, the surface of second interlayer insulating film 22 is flattened by a CMP method, and further, contact holes are formed by using a photolithography technique and a dry etching technique. Here, the contact hole is formed to penetrate second interlayer insulating film 22 in the memory cell region, so that a part of plate electrode 21 is exposed on the bottom of the contact hole. Further, a contact hole (not shown) is formed to penetrate second interlayer insulating film 22, stopper film 12, first interlayer insulating film 9, and bit-covering film 8 in the peripheral circuit region, so that a part of bit line 7 is exposed on the bottom of the contact hole. Next, a tungsten film is formed by a sputtering method so as to fill each of the contact holes, and further, contact plug 23 and bit line contacts (not shown) are formed by removing the tungsten film on second interlayer insulating film 22 by a CMP method.

Next, an aluminum film serving as a wiring is formed on second interlayer insulating film 22 by a sputtering method, and further, a silicon nitride film used as mask layer 25 is formed on the aluminum film by a CVD method. Next, mask layer 25 and the aluminum film are patterned by using a photolithography technique and a dry etching technique, so that upper wiring 24 is formed. Further, third interlayer insulating film 26, which is a silicon oxide film, is formed by a CVD method so as to cover upper wiring 24, and the surface of third interlayer insulating film 26 is flattened by a CMP method. With the above-described process, the structure shown in FIG. 4 is completed.

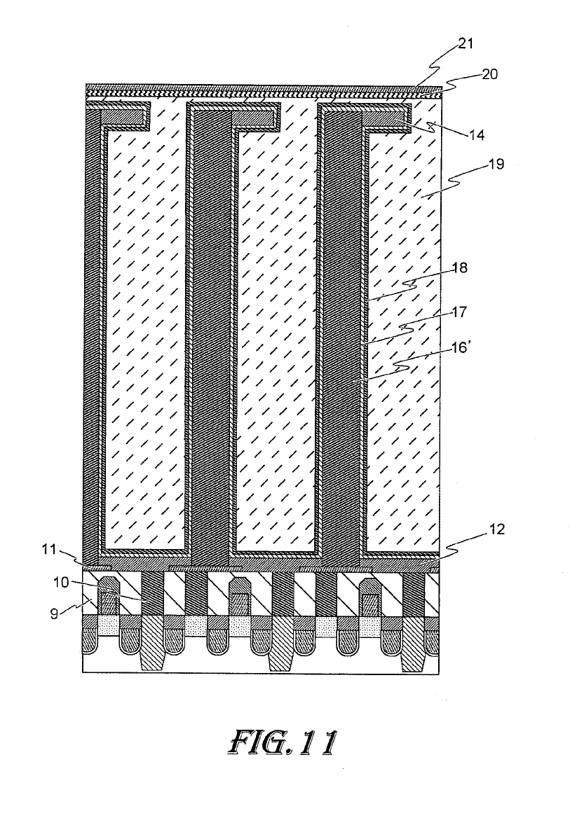

FIG. 11 is a schematic sectional view of a semiconductor device according to another exemplary embodiment. FIG. 11 corresponds to a state after the process as shown in FIG. 10 except that lower electrode 16 having a cylindrical shape is changed to lower electrode 16′ having a columnar shape.

In the following, in the semiconductor device manufacturing method according to the present invention, the manufacturing process of the dielectric film will be particularly described by using Examples, but the present invention is not limited to these Examples.

### Example 1

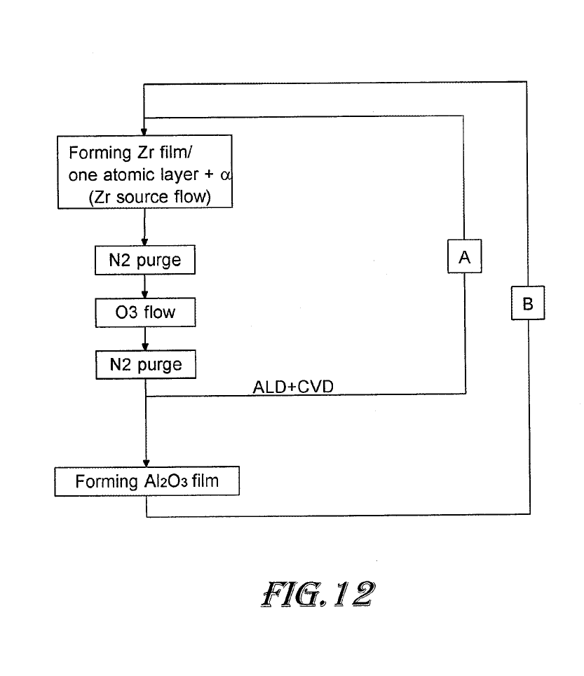

FIG. 12 shows a process flow for forming the dielectric film of Example 1. Note that in Example 1, a dielectric film, the leakage current characteristic of which is improved by partially forming an aluminum oxide layer in a zirconium oxide film, is taken as an example of the dielectric film, but the present invention can be applied to the other dielectric films that can be formed by a known ALD method.

First, as shown in FIG. 12, a Zr film having one atomic layer+α is formed by a Zr source flow for introducing Zr source gas into an ALD apparatus. In a usual ALD method, film formation is performed at a temperature (lower than 220° C.) at which the Zr source gas is not decomposed, and hence the adsorption site (ethyl methylamino group) included in the Zr source (here TEMAZ: tetrakis (ethyl methylamino)zirconium) is adsorbed to the underlying layers (the lower electrode and the support film). A Zr source is not adsorbed on the absorbed Zr source. Thereby, adsorption of one atomic layer can be realized. Next, non-adsorbed Zr source in the film forming space is discharged by N₂ purge, and the adsorbed Zr source is oxidized and decomposed by the subsequent supply of oxidizing gas (O₃ flow), so that one atomic layer of zirconium oxide (ZrO₂) is formed. On the other hand, in the present invention, a part of the Zr source is thermally decomposed, and thereby the decomposition product (Zr atom) is deposited in the gap formed in the Zr source adsorbed to the underlying layer. Even when N₂ purge is performed, the decomposition product entering into the gap in the Zr source is left without being removed, and is oxidized together with the Zr source by the subsequent O₃ flow, so that the zirconium oxide having one atomic layer+α is formed. Thereafter, the O₃ gas and the decomposition product in the film forming space are removed by N₂ purge. The process from the Zr source flow to the second N₂ purge is set as one cycle (A cycle), and the process is repeated until a desired film thickness is obtained. Usually, in order to form a crystalline ZrO₂ film, the process is repeated until the film thickness of 2 nm or more, preferably 4 nm or more, is obtained. Next, an ALD cycle for forming an Al₂O₃ film is performed. The ALD cycle for forming the Al₂O₃ film can be performed by a known method, the examples of which include a usual ALD cycle using trimethylaluminum (TMA) as an Al source. Note that the Al₂O₃ film has a low dielectric constant as compared with that of zirconium oxide, and hence the dielectric constant of the whole dielectric film is reduced by increasing the film thickness of the Al₂O₃ film. Usually, about one or two ALD cycles are sufficient. After formation of the Al₂O₃ film, the zirconium oxide film forming cycle A is again performed. The cycle A, and the Al₂O₃ film forming cycle are performed until a desired film thickness is obtained (referred to as cycle B). Note that the last cycle can be ended in cycle A. According to these sequences, the dielectric film is formed to have a first thickness on the upper surface of the support film and a second thickness thinner than the first thickness on the side surface of the lower electrode. Further, the difference between the first thickness and the second thickness is a difference of the total thicknesses of the zirconium oxide layers at the respective positions.

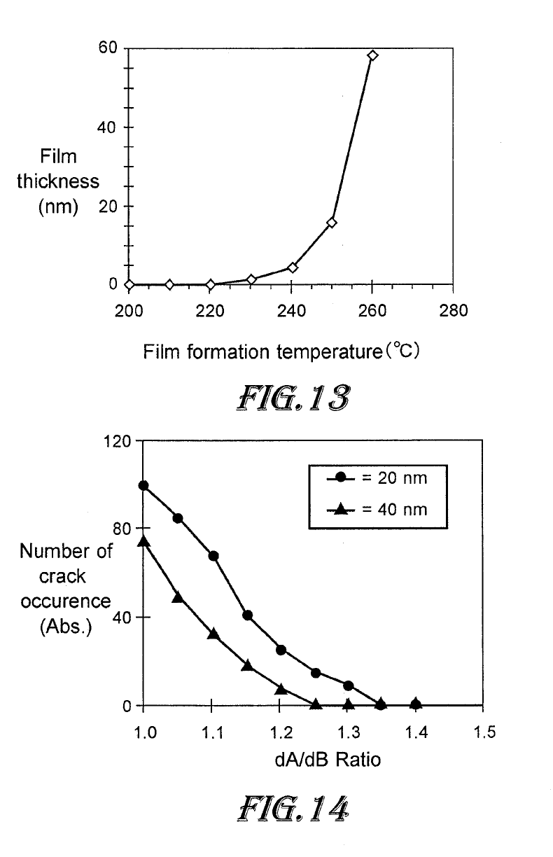

FIG. 13 is a graph showing the thermal decomposition characteristic of Zr source (TEMAZ), and showing the film thickness of zirconium oxide film formed per one cycle with respect to the film formation temperature. It is seen from FIG. 13 that the film is formed to have a thickness of one atomic layer up to 220° C., which is the decomposition temperature of TEMAZ, and that at the temperature exceeding the decomposition temperature of TEMAZ, the film thickness is abruptly increased. Note that any of the results shown in FIG. 13 is obtained under the conditions that the Zr source flow rate is 0.5 cc/min and the Zr source flow time is 10 minutes. When the CVD condition is excessively severe, that is, when the decomposition temperature is set excessively high, the control of film thickness becomes difficult. In the present invention, it is preferred that, when the decomposition temperature of the raw material is set as Td, the film formation is performed at a temperature in the range between Td and Td 20° C. In this Example, the film formation was performed at 230° C.

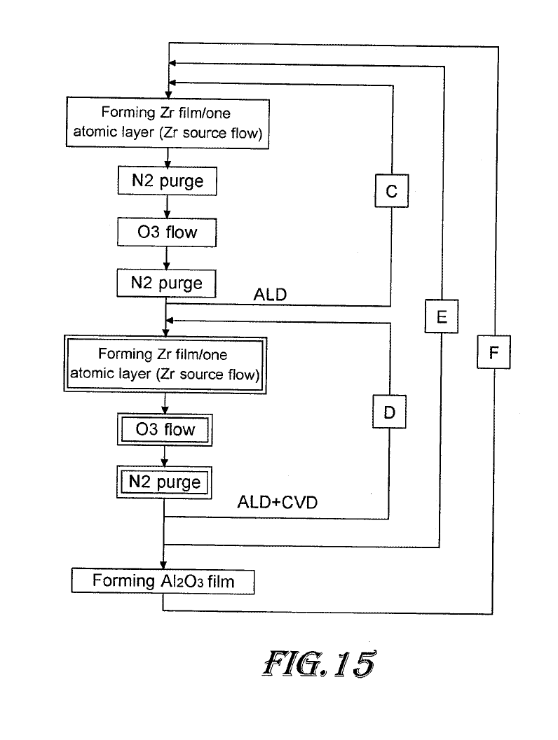

Next, a ratio of dA to dB shown in FIG. 5 is described. FIG. 14 is a graph showing a relationship between the ratio dA/dB and the number of crack occurrences, and the number of crack occurrences was obtained as for two cases: one case where the film thickness of the support film is 20 nm and the other case where the film thickness of the support film is 40 nm. The ratio where dA/dB=1 corresponds to the case of the related art. In the case of 20 nm-thick, about one hundred cracks are caused by the related art. As can be seen from FIG. 14, the ratio dA/dB is increased, the number of crack occurrences is reduced. When the ratio dA/dB is set to 1.25 in the case of 40 nm-thick, or even when the ratio dA/dB is set to 1.35 in the case of 20 nm-thick, the number of crack occurrences is reduced to zero. Here, the film formation was performed by setting dB as dB=8 nm. That is, the first thickness is preferably a thickness sufficient to suppress an occurrence of cracks in the support film.

### Example 2

In Example 1, in order to form a film with one atomic layer+α, the CVD condition based on thermal decomposition is added, but a CVD condition without depending on thermal decomposition can also be added.

FIG. 15 is a flow chart for explaining a film forming flow of this Example. First, usual ALD cycle C is repeated by a desired number of times to form a zirconium oxide film. In this stage, dA/dB is set as dA/dB=1.

Next, the N₂ purge after the Zr source flow is omitted so that the Zr source is left in the gas phase. When the O₃ flow is performed in this state, oxidative decomposition is caused in the gas phase at the same time with oxidative decomposition of the Zr source adsorbed in the underlying layer (by the usual ALD method), and thereby zirconium oxide formed by the gas phase reaction is deposited in a large amount on the upper side of the substrate, that is, the upper surface of the support film. Thereafter, the N₂ purge is performed. The cycle of the series of processes is set as cycle D and is repeated by one or more times. The Zr source flow in cycle D is performed at a temperature less than the decomposition temperature of the raw material. In some cases, the CVD condition based on thermal decomposition can also be combined with cycle D. Cycles C and D are performed until a desired film thickness is obtained (referred to as cycle E).

Thereafter, an ALD cycle for forming an Al₂O₃ film is performed. The ALD cycle for forming the Al₂O₃ film is the same as that in Example 1. After formation of the Al₂O₃ film, cycle E for forming a zirconium oxide film are again performed. Cycle E and the cycle for forming an Al₂O₃ film are performed until a desired film thickness is obtained (also referred to as cycle F). Note that the series of the cycles can be ended at cycle C or cycle D.

The present invention also includes embodiments as described below:

I. A method for manufacturing a semiconductor device comprising:
forming a hole in a stacked structure of a sacrificial insulating film and a support film;
forming, in the hole, a first conductor film serving as a lower electrode of a capacitor;
forming an opening in the support film;
removing the sacrificial insulating film via the opening; and
forming a dielectric film on the exposed first conductor film and the exposed support film,
wherein the dielectric film is formed to have a first thickness on the upper surface of the support film and a second thickness thinner than the first thickness on the side surface of the lower electrode.

II. The method for manufacturing a semiconductor device according to item I, wherein the dielectric film is formed by an ALD method in which a film forming cycle is repeated, the film forming cycle including supplying and adsorbing a raw material gas, purging the raw material gas, supplying oxidizing gas, and purging a film forming space, and is formed by adding a CVD condition to a part of the film forming cycle.

III. The method for manufacturing a semiconductor device according to item II, wherein the CVD condition is that, when the decomposition temperature of the raw material gas is set as Td, the supply and adsorption of the raw material gas are performed at a temperature in the rage of from Td to Td+20° C.

IV. The method for manufacturing a semiconductor device according to item II, wherein the CVD condition is that the supply of the oxidizing gas is performed without purging the raw material gas.

V. The method for manufacturing a semiconductor device according to item II, wherein the dielectric film is formed by using a raw material gas containing zirconium.

VI. The method for manufacturing a semiconductor device according to item V, wherein the dielectric film is formed in such a manner that a film forming cycle using a raw material gas containing aluminum is performed one or more times in the film forming cycle using the raw material gas containing zirconium.

VII. The method for manufacturing a semiconductor device according to item VI, wherein the CVD condition is added to the film forming cycle using the raw material gas containing zirconium.

VIII. The method for manufacturing a semiconductor device according to item I, wherein the dielectric film is formed so as to make a ratio of dA/dB, in which dA is the first thickness and dB is the second thickness, be 1.25 or more.

IX. The method for manufacturing a semiconductor device according to item I, wherein the dielectric film is formed so as to make the second thickness become a thickness satisfying a predetermined capacitance value of the capacitor.

X. The method for manufacturing a semiconductor device according to item I, wherein the film thickness of the support film is 60 nm or less.

XI. The method for manufacturing a semiconductor device according to item X, further comprising forming, on the dielectric film, a second conductor film serving as the upper electrode of the capacitor.

What is claimed is:

1. A semiconductor device provided with a capacitor comprising:
a cylindrical or columnar lower electrode;
a support film in contact with the upper portion of the lower electrode;
a dielectric film covering the lower electrode and the support film; and
an upper electrode facing the lower electrode with the dielectric film interposed therebetween,
wherein the dielectric film has a first thickness on the upper surface of the support film and a second thickness thinner than the first thickness on the side surface of the lower electrode.

2. The semiconductor device according to claim 1, wherein the second thickness is a thickness of the dielectric film at a position lower than the position at which the lower electrode is in contact with the support film.

3. The semiconductor device according to claim 2, wherein in the dielectric film, a ratio of dA/dB, in which dA is the first thickness and dB is the second thickness, is 1.25 or more.

4. The semiconductor device according to claim 1, wherein the support film is in contact with the upper side edge of the lower electrode.

5. The semiconductor device according to claim 4, wherein the first thickness is a maximum thickness of the dielectric film.

6. The semiconductor device according to claim 1, wherein the second thickness of the dielectric film is a thickness that satisfies a predetermined capacitance value of the capacitor.

7. The semiconductor device according to claim 1, wherein the support film has a film thickness of 60 nm or less.

8. The semiconductor device according to claim 7, wherein the support film comprises silicon nitride.

9. The semiconductor device according to claim 1, wherein the dielectric film comprises zirconium oxide.

10. The semiconductor device according to claim 9, wherein the dielectric film is a film formed by interposing an aluminum oxide layer between layers including the zirconium oxide.

11. The semiconductor device according to claim 10, wherein the difference between the first thickness and the second thickness is a difference of the total thicknesses of the layers including the zirconium oxide at the respective positions.

12. The semiconductor device according to claim 1, wherein the lower electrode is connected to a contact pad and further the contact pad is connected to an impurity diffusion layer via a contact plug.

13. The semiconductor device according to claim 12, wherein the device comprises a memory cell region comprising a plurality of the capacitors and a peripheral circuit region provided around the memory cell region, and the support film is provided within the memory cell region.

14. A semiconductor device comprising:
a first conductor film perpendicularly standing on a substrate;
a support film in contact with the upper portion of the first conductive film; and
a dielectric film covering the first conductor film and the support film,
wherein the dielectric film has a first thickness on the upper surface of the support film and a second thickness thinner than the first thickness on the side surface of the first conductor film at a position lower than the position at which the first conductor film is in contact with the support film.

15. The semiconductor device according to claim 14, wherein the first thickness is a thickness sufficient to suppress an occurrence of cracks in the support film.

16. The semiconductor device according to claim 14, wherein the first conductor film is a lower electrode of a capacitor, and the second thickness is a thickness that satisfies a predetermined capacitance value of the capacitor.

17. The semiconductor device according to claim 16, wherein the lower electrode is formed in a cylindrical or columnar shape having a sufficient surface area that satisfies a predetermined capacitance value of the capacitor.

18. The semiconductor device according to claim 17, further comprising an upper electrode facing the lower electrode with the dielectric film interposed therebetween.

19. The semiconductor device according to claim 18, wherein the lower electrode has a cylindrical shape and the upper electrode is faced an inner wall of the lower electrode with the dielectric film interposed therebetween.

20. The semiconductor device according to claim 18, wherein the upper electrode comprises a second conductor film formed on the dielectric film and a filling film formed on the second conductor film to fill gaps under the support film.
